(19) United States
(12) Patent Application Publication
(10) Pub. No.: US 2024/0203686 A1
(43) Pub. Date: Jun. 20, 2024

(54) GUIDE PIN, SYSTEM FOR PRECISELY CONTROLLING SPECIMEN INCLUDING THE SAME, AND METHOD FOR OBSERVING SPECIMEN USING THE SAME

(71) Applicant: Samsung Electronics Co., Ltd., Suwon-si (KR)

(72) Inventor: Kilho Lee, Suwon-si (KR)

(21) Appl. No.: 18/366,355

(22) Filed: Aug. 7, 2023

(30) Foreign Application Priority Data
Dec. 14, 2022 (KR) 10-2022-0174507
Mar. 20, 2023 (KR) 10-2023-0036041

(51) Int. Cl. H01J 37/20

(52) U.S. Cl. CPC H01J 37/20; H01J 2237/20214; H01J 2237/20278; H01J 2237/208

(57) ABSTRACT

A guide pin includes a support part and a frictional column coupled to the support part, and the support part includes a lower support member including a screw structure on an outer surface thereof, and an upper support member on the lower support member. The frictional column surrounds an outer surface of the upper support member. A hardness of the frictional column is lower than a hardness of the support part.

### CROSS-REFERENCE TO RELATED APPLICATIONS

This application claims priority under 35 U.S.C. § 119 to Korean Patent Application Nos. 10-2022-0174507 and 10-2023-0036041 filed on Dec. 14, 2022 and Mar. 20, 2023, respectively, in the Korean Intellectual Property Office, the disclosures of which are incorporated by reference herein in their entireties.

### BACKGROUND

Embodiments of the present disclosure described herein relate to a guide pin, a system for precisely controlling a specimen including the same, and a method for observing a specimen by using the same and more particularly, relate to a guide pin that may reduce frictions between a gonio pipe and a guide pin, and a system for precisely controlling a specimen.

In a semiconductor process, a substrate is used to manufacture a semiconductor. Various pieces of equipment may be used to identify a quality of the manufactured product. Among them, a transmission electron microscope (TEM) may be used. The TEM is a kind of an electronic microscope that may generate transmitted waves by projecting electron beams with an electron gun such that the electron beams pass through a specimen and allow a user to observe an image enlarged by allowing them to pass through the electronic lens while the image is collected by a fluorescent plate. Then, to observe the specimen while fixing and precisely moving the specimen, the specimen is disposed in a holder and the holder is inserted into a gonio pipe.

### SUMMARY

Embodiments of the present disclosure provide a guide pin that may reduce friction between the guide pin and a gonio pipe, a system for precisely controlling a specimen including the same, and a method for observing a specimen by using the same.

Embodiments of the present disclosure provide a guide pin that may prevent a change in a shape of an insertion part of a gonio pipe, a system for precisely controlling a specimen including the same, and a method for observing a specimen by using the same.

Embodiments of the present disclosure provide a guide pin that may reduce a residual stress of an insertion part of a gonio pipe, a system for precisely controlling a specimen including the same, and a method for observing a specimen by using the same.

Embodiments of the present disclosure provide a guide pin that may prevent breaking of the guide pin, a system for precisely controlling a specimen including the same, and a method for observing a specimen by using the same.

The problems to be solved by the present disclosure are not limited to the above-described ones, and the other unmentioned problems will be clearly understood from the following description by a person of ordinary skill in the art.

According to an aspect of the present disclosure, a guide pin includes a support part and a frictional column coupled to the support part, the support part includes a lower support member including a screw structure on an outer surface thereof, and an upper support member on the lower support member, the frictional column surrounds an outer surface of the upper support member, and a hardness of the frictional column is lower than a hardness of the support part.

According to another aspect of the present disclosure, a system for precisely controlling a specimen includes a holder configured to insert the specimen into an electronic microscope, and a goniometer stage configured to precisely control a motion of the specimen, the holder includes a handle part, a specimen mounting part configured to fix the specimen, a coupling part connecting the handle part and the specimen mounting part, and a guide pin configured to couple the holder to an interior of the goniometer stage, the guide pin includes a support part and a frictional column coupled to the support part, the support part includes a lower support member including a screw structure on an outer surface thereof to be coupled to the holder, and an upper support member on the lower support member, and the frictional column surrounds an outer surface of the upper support member.

According to another aspect of the present disclosure, a method for observing a specimen includes mounting the specimen in a holder, inserting the holder into a gonio pipe of a goniometer stage, and observing the specimen while causing electron beams to pass through the specimen, the holder includes a handle part, a specimen mounting part to which the specimen is mounted, a coupling part connecting the handle part and the specimen mounting part, and a guide pin coupling the holder and the goniometer stage, the guide pin includes a support part and a frictional column coupled to the support part, the support part includes a lower support member including a spiral screw shape on an outer surface thereof to be coupled to the holder, and an upper support member having a column shape on the lower support member, and the frictional column surrounds an outer surface of the upper support member.

Details of other embodiments are included in the detailed description and the drawings.

### BRIEF DESCRIPTION OF THE FIGURES

The above and other objects and features of the present disclosure will become apparent by describing in detail embodiments thereof with reference to the accompanying drawings.

FIG. 1 is a schematic view illustrating a system for precisely controlling a specimen, in which a holder is inserted into a gonio pipe and is coupled to an electronic microscope according to embodiments of the present disclosure;

FIG. 2 is a schematic view illustrating a system for precisely controlling a specimen, in which a holder is inserted into a gonio pipe and is coupled to an electronic microscope according to embodiments of the present disclosure;

FIG. 3 is a plan view illustrating linear movement and rotation of a holder according to embodiments of the present disclosure;

FIG. 4 is a perspective view illustrating a holder according to embodiments of the present disclosure;

FIG. 5 is a plan view illustrating a holder according to embodiments of the present disclosure;

FIG. 6 is an enlarged view illustrating a specimen mounting part that is a part of a holder according to embodiments of the present disclosure;

FIG. 7 is a perspective view illustrating a guide pin according to embodiments of the present disclosure;

FIG. 8 is a side view illustrating a guide pin according to embodiments of the present disclosure;

FIG. 9 is a plan view illustrating a guide pin according to embodiments of the present disclosure;

FIG. 10 is a perspective view illustrating a gonio pipe having a slit according to embodiments of the present disclosure;

FIG. 11 is an enlarged view illustrating a part of a gonio pipe according to embodiments of the present disclosure;

FIG. 12 is a plan view illustrating a part of a gonio pipe according to embodiments of the present disclosure;

FIG. 13 is a flowchart illustrating a method for observing a specimen according to embodiments of the present disclosure;

FIG. 14 is a perspective view illustrating a guide pin according to embodiments of the present disclosure;

FIG. 15 is a perspective view illustrating a guide pin according to embodiments of the present disclosure; and

FIG. 16 is a perspective view illustrating a guide pin according to embodiments of the present disclosure.

### DETAILED DESCRIPTION

Hereinafter, embodiments of the present disclosure will be described with reference to the accompanying drawings. Throughout the specification, the same reference numerals may refer to the same components.

Hereinafter, D1 may denote a first direction, D2 that crosses (or is perpendicular to) the first direction D1 may denote a second direction, and D3 that crosses (or is perpendicular to) the first direction D1 and the second direction D2 may denote a third direction.

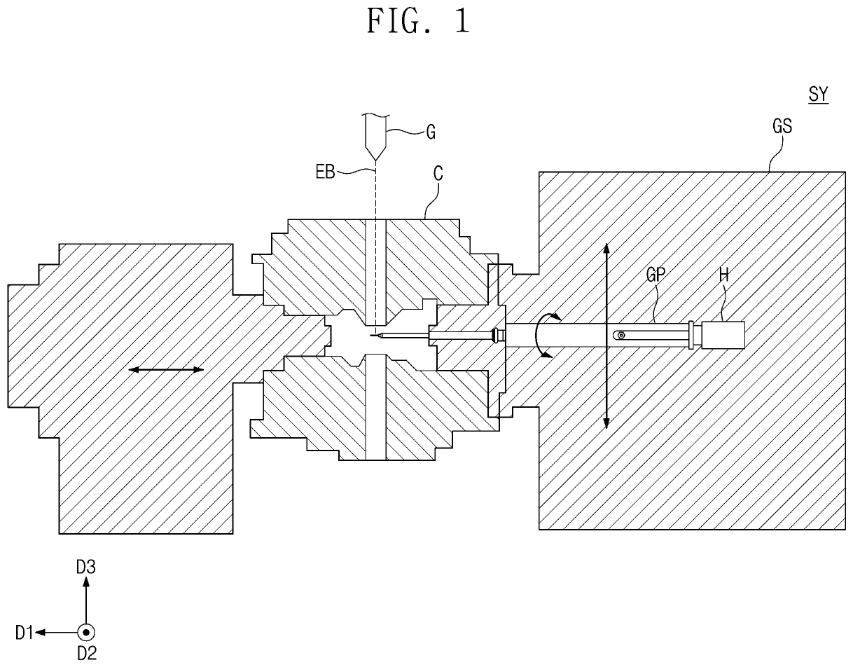

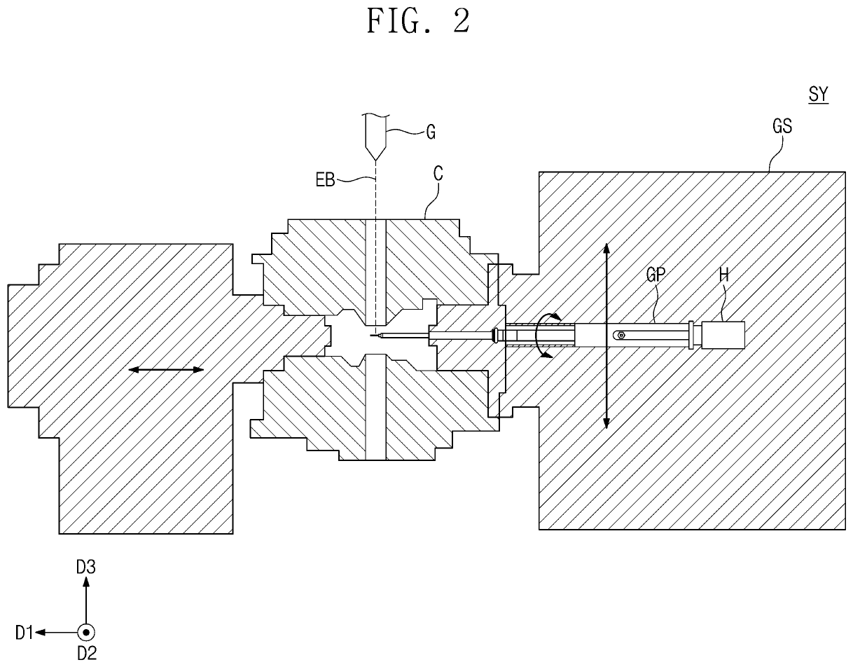

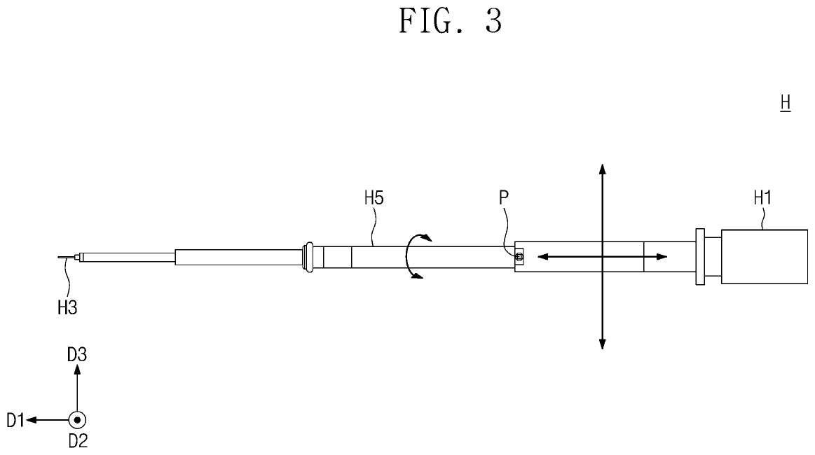

FIGS. 1 and 2 are schematic views illustrating a system SY for precisely controlling a specimen, in which a holder H is inserted into a gonio pipe GP and is coupled to an electronic microscope according to embodiments of the present disclosure, and FIG. 3 is a plan view illustrating linear movement and rotation of the holder H according to embodiments of the present disclosure.

Referring to FIGS. 1 and 2, the system SY for precisely controlling a specimen may be provided. The system SY for precisely controlling a specimen may fix and/or move the specimen in a process of observing the specimen by using an electronic microscope. By using the electronic microscope, the specimen may be observed by recognizing motions of electrons in a vacuum state. The electronic microscope may include a scanning electron microscope (SEM) or a transmission electron microscope (TEM). By using the transmission electron microscope, electronic rays that pass through the specification may be observed after being enlarged by an electronic lens. A vacuum environment may be necessary to use the electronic rays. The transmission electron microscope may include an electron gun G that projects electron beams EB, a condensing lens that collects the electron beams EB that exit from the electron gun G, an object lens that forms an image, and a detector that may record the image. The condensing lens, the object lens, and the detector may be included in a chamber C. In other words, the chamber C may include the condensing lens, the object lens, and the detector. The chamber C may be maintained in a vacuum state. The chamber C may include a through-hole in an interior thereof. The holder H may insert the specimen into the through-hole. The electron beams EB may exit from the electron gun G through the through-hole and may reach the specimen. The specimen has to be fixed or precisely moved so that the electron beams EB pass through the specimen. Accordingly, the specimen has to be precisely controlled by the system SY for precisely controlling a specimen. To achieve this, the system SY for precisely controlling a specimen may include a goniometer stage GS and the holder H. The goniometer stage GS may include the gonio pipe GP. Through the gonio pipe GP, the holder H may be inserted into the chamber C. Detailed contents of the gonio pipe GP will be described below.

Referring to FIG. 3, the goniometer stage GS may move the holder H. For example, the goniometer stage GS may move the holder H in three axes. To achieve this, the goniometer stage GS may include a 3-axis driving motor that may move the holder H in a first direction that is an extension direction of a lengthwise direction of the holder H, a second direction that crosses (or is perpendicular to) the first direction, and a third direction that crosses (or is perpendicular to) the first direction and the second direction. Additionally or alternatively, the goniometer stage GS may rotate the holder H. To achieve this, the goniometer stage GS may have a first rotation driving motor that may rotate the holder H about an axis that is parallel to the first direction. In more detail, the goniometer stage GS may allow the holder H to be linearly moved (the first direction, the second direction, and the third direction) at three degrees of freedom and be rotated at one degree of freedom. More detailed description of the holder H will be provided below.

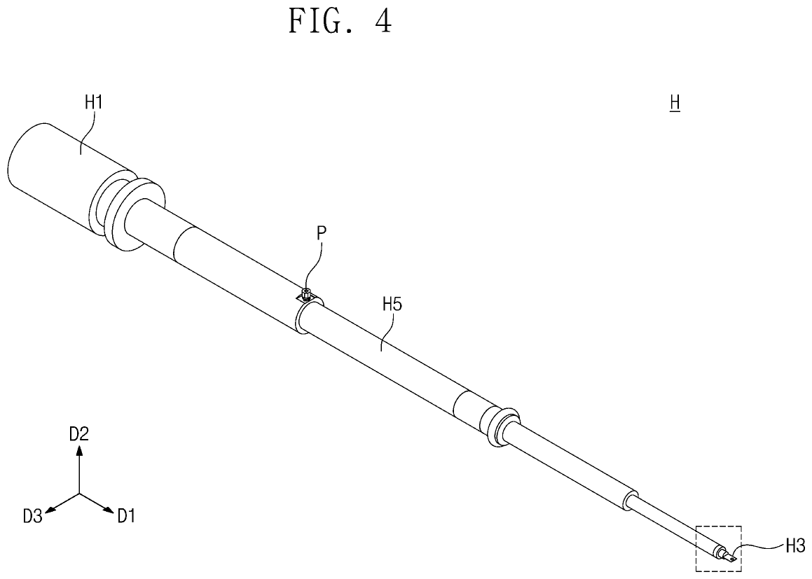

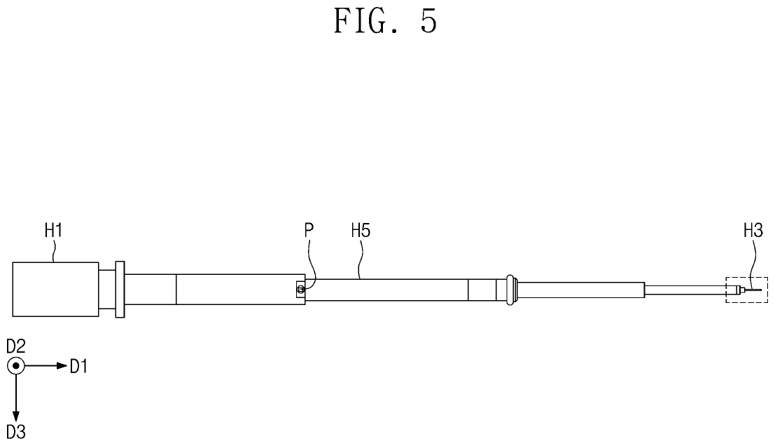

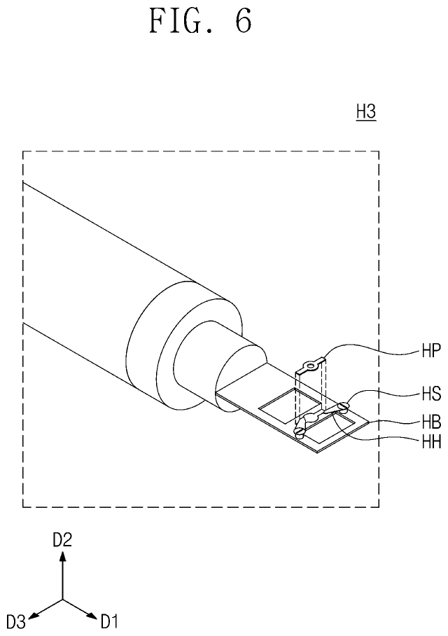

FIG. 4 is a perspective view illustrating a holder H according to embodiments of the present disclosure. FIG. 5 is a plan view illustrating a holder H according to embodiments of the present disclosure. FIG. 6 is an enlarged view illustrating a specimen mounting part H3 that is a part of a holder H according to embodiments of the present disclosure.

Referring to FIGS. 4 and 5, the holder H may move the specimen into the electronic microscope. The holder H may include a handle part H1, a specimen mounting part H3 that may dispose and fix the specimen, a coupling part H5 that connects the handle part H1 and the specimen mounting part H3, a guide pin P that may couple the holder H to an interior of the goniometer stage GS. The guide pin P will be described in detail below.

The handle part H1 may be formed on one side or end of the holder H. The handle part H1 may be used when a user of the electronic microscope pushes the holder H into the goniometer stage GS. The handle part H1 may have a cylindrical shape. The handle part H1 may include a continuous groove on an outer surface thereof to increase a frictional force during manipulation thereof. However, the present disclosure is not limited thereto.

Referring to FIG. 6, the specimen may be installed in the specimen mounting part H3. The specimen mounting part H3 may be formed on an opposite side of the holder H (e.g., an end opposite the handle H1). As an example of the specimen mounting part H3, the specimen mounting part H3 may include a mounting body HB, a fastening screw HS, a fixing plate HP, and a fixing pin HH. However, the present disclosure is not limited to the above configuration.

The mounting body HB may have a thin plate shape. The mounting body HB may be provided with a through-hole of various shapes.

The fastening screw HS may be provided with a groove on an upper surface thereof. By rotating the groove, the fastening screw HS may be coupled to the mounting body HB. By rotating the groove to the contrary or opposite direction, the fastening screw HS may be separated from the mounting body HB.

The fixing pin HH may be connected to the fastening screw HS. In more detail, one side or end of the fixing pin HH may be connected to the fastening screw HS. A motion of the fixing pin HH may be restricted by the fastening screw HS. In more detail, a resistance may be caused in the motion of the fixing pin HH as the fastening screw HS is fastened, and the fixing pin HH may be fixed as a degree of freedom thereof becomes lower or decrease. The resistance of the fixing pin HH may be decreased as the fastening screw HS is released, and a degree of freedom thereof may become higher or increase.

The fixing plate HP may be disposed on the specimen. The fixing plate HP may fix the specimen. The fixing plate HP may have a form, in which a circular plate is coupled to a center of a bar plate. The circular plate may have a form, in which a center thereof is hollow such that the specimen may be precisely observed. A width of the circular plate may be smaller than a length of the bar plate. Opposite sides of the bar plate may be pressed by the fixing pin HH. The fixing plate HP may be fixed by the pressing of the fixing pin HH to fix the specimen to the holder H.

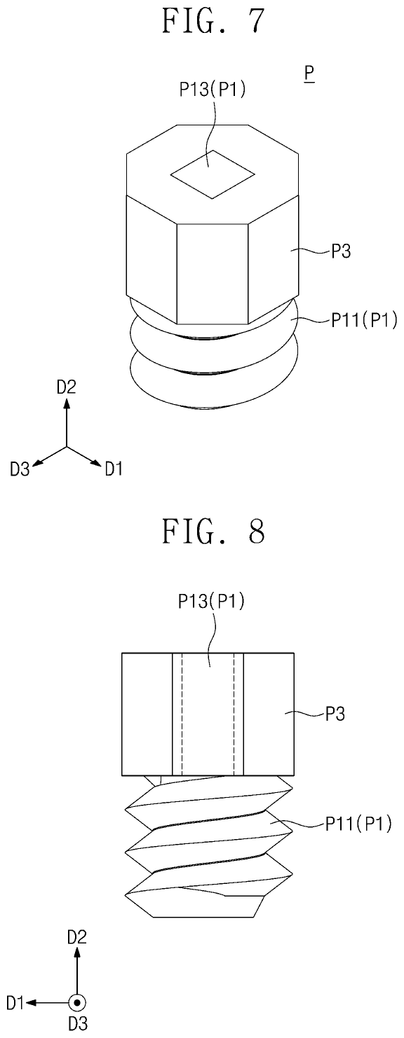

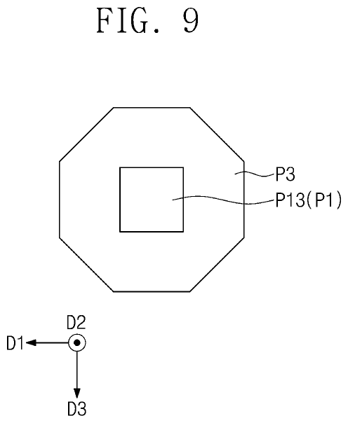

FIG. 7 is a perspective view illustrating the guide pin “P” according to embodiments of the present disclosure. FIG. 8 is a side view illustrating the guide pin P according to embodiments of the present disclosure. FIG. 9 is a plan view illustrating the guide pin P according to embodiments of the present disclosure.

Referring to FIGS. 7, 8, and 9, the guide pin P may include a support part P1, and a frictional column P3 that is coupled to the support part P1. The support part P1 may include a lower support member P11 having a screw structure on an outer surface thereof, and an upper support member P13 on the lower support member P11.

The support part P1 may include a metal. In more detail, the support part P1 may include beryllium bronze, iron, and/or bronze. Due to the screw shape of the lower support member P11, the support part P1 may be coupled to or separated from the holder H. The screw shape may be a left-handed screw or a right-handed screw. A height of the lower support member P11 may be about 1.9 mm to about 2.3 mm. In more detail, the height of the lower support member P11 may be about 2.1 mm. A height of the upper support member P13 may be about 2.1 mm to about 2.5 mm. In more detail, the height of the upper support member P13 may be about 2.3 mm. An outer surface of the upper support member P13 may include a polygonal shape.

The frictional column P3 may surround the outer surface of the upper support member P13. In other words, an inner surface of the frictional column P3 may have the same shape as that of the outer surface of the upper support member P13 in a plan view. The frictional column P3 and the support part P1 may include different materials. In more detail, a hardness of the frictional column P3 may be lower than a hardness of the support part P1. The hardness mentioned in the specification may mean mohs hardness, shore hardness, or the like. The frictional column P3 may include engineering plastic. In more detail, the frictional column P3 may include one of polyester ether ketone (PEEK), polyamide (PA), or duraflon. A height of the frictional column P3 may be substantially the same as a height of the upper support member P13. An outer surface of the frictional column P3 may include a polygonal shape.

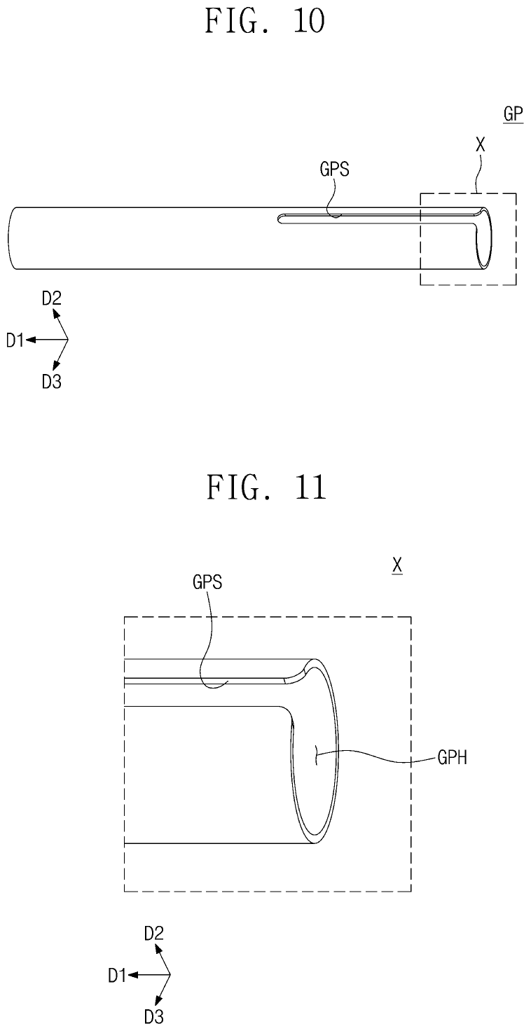

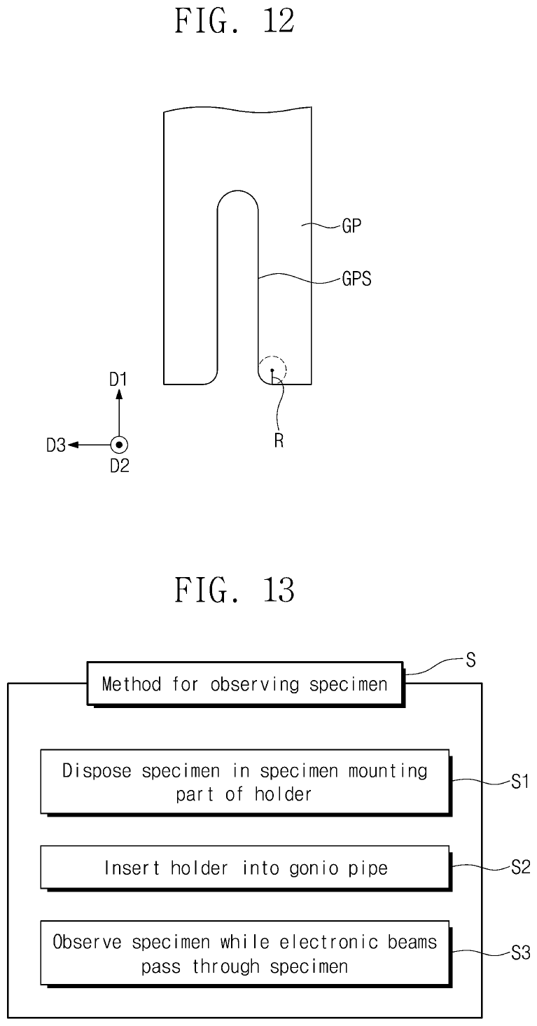

FIG. 10 is a perspective view illustrating the gonio pipe GP having a slit GPS according to embodiments of the present disclosure. FIG. 11 is an enlarged view illustrating a part of the gonio pipe GP according to embodiments of the present disclosure. FIG. 12 is a plan view illustrating a part of the gonio pipe GP according to embodiments of the present disclosure.

Referring to FIG. 10, the gonio pipe GP may have a pipe shape (e.g., hollow cylindrical shape). By using the gonio pipe GP, the specimen may be located in the electronic microscope. The gonio pipe GP may fix the specimen such that the specimen is not moved. The gonio pipe GP may be provided with an interior space GPH and the slit GPS.

The interior space GPH may extend in the first direction that is an extension direction of the coupling part H5 and may pass through or be defined by the gonio pipe GP. The slit GPS may extend in a direction that crosses the first direction from the interior space GPH and may expose the interior space GPH. The slit GPS may extend in the first direction from an end of the gonio pipe GP. A length of the slit GPS in the first direction may be smaller than a length of the gonio pipe GP in the first direction, and one side of the slit GPS may be connected to one end of the gonio pipe GP. A hardness of the gonio pipe GP may be higher than a hardness of the frictional column P3. In other words, the hardness of the frictional column P3 may be lower than the hardness of the gonio pipe GP. Accordingly, when a friction occurs between the frictional column P3 and the gonio pipe GP, not the gonio pipe GP but the frictional column P3 may be worn. The gonio pipe GP may include bronze.

Referring to FIGS. 11 and 12, the slit GPS and a corner of an insertion part or portion X, to which one end of the gonio pipe GP is connected or present, may be additionally machined in various schemes. In more detail, the insertion part X may include a filleted or chamfered structure. A corner of the insertion part X may be rounded through filleting. A radius R of curvature of the filleted corner of the insertion part X may be 3 mm or more. The corner of the insertion part X may be cut obliquely through chamfering.

FIG. 13 is a flowchart illustrating a method S for observing a specimen according to embodiments of the present disclosure.

Referring to FIG. 13, the method for observing a specimen may include operation S1 of disposing the specimen in the specimen mounting part H3 of the holder H, operation S2 of inserting the holder H into the gonio pipe GP of the goniometer stage GS, and operation S3 of observing the specimen while the electron beams pass through the specimen.

Referring to FIGS. 13 and 6, operation S1 of disposing the specimen in the specimen mounting part H3 of the holder H may include an operation of disposing the specimen in the mounting body HB, an operation of disposing the fixing plate HP having a hollow central area on the specimen such that the specimen may be precisely observed while being fixed, an operation of locating one side of the fixing pin HH on one side of the fixing plate HP, and an operation of fixing the fixing pin HH by rotating and fastening the fastening screw HS to fix the fixing plate HP.

Referring to FIGS. 13 and 1, operation S2 of inserting the holder H into the gonio pipe GP of the goniometer stage GS may include an operation of bringing the holder H into contact with the gonio pipe GP, an operation of changing an interior of the gonio pipe GP into a vacuum state (e.g., using a vacuum pump), an operation of locating the guide pin P in the slit GPS through primary rotation thereof, and an operation of inserting the guide pin P to an end of the slit GPS.

Referring to FIGS. 13 and 1, operation S3 of observing the specimen while the electron beams pass through the specimen may include an operation of projecting the electron beams with an electron gun, an operation of collecting the electron beams that pass through the specimen with the condensing lens, an operation of enlarging an image with the object lens, and the operation of forming and recording the enlarged image with the detector.

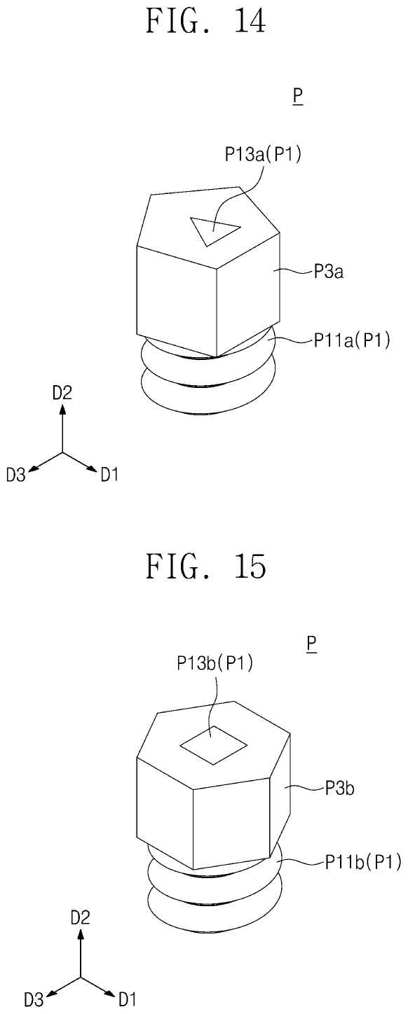

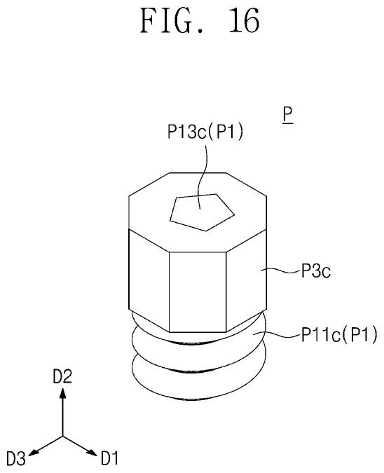

FIGS. 14, 15, and 16 are perspective views illustrating the guide pin P according to outer surfaces of the upper support member P13 and the frictional column P3 according to embodiments of the present disclosure.

FIGS. 14, 15, and 16 include substantially the same structure as that of the guide pin P of FIG. 7, and thus a description of the contents that are substantially the same or similar to the description made with reference to FIGS. 7 to 9 is omitted in the interest of brevity. Referring to FIGS. 14, 15, and 16, the outer surface or perimeter of the upper support member P13 may include a polygonal shape as described above. In more detail, the outer surface or perimeter of the upper support member P13 may include one of a triangular shape P13a (P1), a rectangular shape P13b (P1), and a pentagonal shape P13c (P1) in a plan view. The outer surface or perimeter of the frictional column P3, as described above, may include a polygonal shape. In more detail, the outer surface or perimeter of the frictional column P3 may include one of a pentagonal shape P3a, a hexagonal shape P3b, and an octagonal shape P3c in a plan view. A combination of the upper support member P13 and the frictional column P3 is not limited to the examples of FIGS. 14, 15, and 16, and other combinations are possible.

According to the guide pin, the system for precisely controlling a specimen including the same, and the method for observing a specimen using the same according to embodiments of the present disclosure, friction between the guide pin and the gonio pipe may be reduced. In more detail, because the frictional column may be manufactured of plastic, a frictional coefficient thereof may be reduced.

According to the guide pin, the system for precisely controlling a specimen including the same, and the method for observing a specimen using the same according to embodiments of the present disclosure, a change in the shape of the insertion part of the gonio pipe may be prevented. The frictional column may generate friction with the slit of the gonio pipe when the holder is rotated after being inserted into the gonio pipe and coupled to the gonio pipe. The hardness of the gonio pipe may be higher than that of the slit of the frictional column, and therefore not the gonio pipe but the frictional column may be worn. Accordingly, a change in the shape of the insertion part of the gonio pipe may be reduced. In more detail, the change in the shape of the insertion part of the gonio pipe may be improved by 98%.

According to the guide pin, the system for precisely controlling a specimen including the same, and the method for observing a specimen using the same according to embodiments of the present disclosure, a residual stress of the insertion part of the gonio may be reduced. In more detail, the residual stress of the insertion part of the gonio pipe with filleting of 3 mm may be remarkably improved. The residual stress of the insertion part of the gonio pipe may be improved by about 50%.

According to the guide pin, the system for precisely controlling a specimen including the same, and the method for observing a specimen using the same according to embodiments of the present disclosure, breaking of the guide pin may be prevented. When the guide pin is formed of a single material without using the frictional column and the hardness of the guide pin is higher than that of the gonio pipe, the shape of the insertion part of the gonio pipe may be deformed. When the guide pin formed of a single material without the frictional column is used and the hardness of the guide pin is lower than that of the gonio pipe, the guide pin may be broken. The guide pin may not be broken while the shape of the insertion part of the gonio pipe is not deformed in spite of the friction between the frictional column and the gonio pipe by the frictional column of the guide pin.

According to the guide pin, the system for precisely controlling a specimen including the same, and the method for observing a specimen by using the same, friction between the guide pin and the gonio pipe may be reduced.

According to the guide pin, the system for precisely controlling a specimen including the same, and the method for observing a specimen by using the same, a change in the shape of the insertion part of the gonio pipe may be prevented.

According to the guide pin, the system for precisely controlling a specimen including the same, and the method for observing a specimen by using the same, a residual stress of the insertion part of the gonio pipe may be reduced.

According to the guide pin, the system for precisely controlling a specimen including the same, and the method for observing a specimen by using the same, breaking of the guide pin may be prevented.

The effects to be solved by the present disclosure are not limited to the above-described ones, and the other unmentioned effects will be clearly understood from the present disclosure by a person of ordinary skill in the art.

Although the embodiments of the present disclosure have been described with reference to the accompanying drawings, it will be understood that the present disclosure can be carried out in other forms while the technical spirits and essential feature are not changed. Therefore, it should be understood that the embodiments described above are illustrative in all aspects and are not limiting.

What is claimed is:

1. A guide pin comprising:
a support part; and
a frictional column coupled to the support part,
wherein the support part includes:
a lower support member including a screw structure on an outer surface thereof; and
an upper support member on the lower support member,
wherein the frictional column surrounds an outer surface of the upper support member, and
a hardness of the frictional column is lower than a hardness of the support part.

2. The guide pin of claim 1, wherein the support part includes beryllium copper.

3. The guide pin of claim 1, wherein the frictional column includes one of polyester ether ketone (PEEK), polyamide (PA), and duraflon.

4. The guide pin of claim 1, wherein the outer surface of the upper support member includes one of a triangular shape, a rectangular shape, and a pentagonal shape.

5. The guide pin of claim 1, wherein an outer surface of the frictional column includes one of a pentagonal shape, a hexagonal shape, and an octagonal shape.

6. The guide pin of claim 1, wherein a height of the lower support member is 1.9 mm to 2.3 mm.

7. The guide pin of claim 1, wherein a height of the upper support member is 2.1 mm to 2.5 mm.

8. A system for precisely controlling a specimen, the system comprising:
a holder configured to insert the specimen into an electronic microscope; and
a goniometer stage configured to precisely control a motion of the specimen,
wherein the holder includes:
a handle part;
a specimen mounting part configured to fix the specimen;
a coupling part connecting the handle part and the specimen mounting part; and
a guide pin configured to couple the holder to an interior of the goniometer stage,
wherein the guide pin includes:
a support part; and
a frictional column coupled to the support part,
wherein the support part includes:
a lower support member including a screw structure on an outer surface thereof to be coupled to the holder; and
an upper support member on the lower support member, and
wherein the frictional column surrounds an outer surface of the upper support member.

9. The system of claim 8, wherein the goniometer stage includes a 3-axis driving motor configured to move the holder in a first direction in which the coupling part extends, a second direction perpendicular to the first direction, and a third direction perpendicular to the first direction and the second direction.

10. The system of claim 9, wherein the goniometer stage further includes a first rotation driving motor configured to rotate the holder about an axis that extends in the first direction.

11. The system of claim 8, wherein the goniometer stage includes a gonio pipe configured to fix the holder,
wherein the gonio pipe provides:
an interior space extending in a first direction in which the coupling part extends; and
a slit extending in the first direction through which the interior space is exposed, and
wherein a length of the slit in the first direction is smaller than a length of the gonio pipe in the first direction, and one end of the slit is at one end of the gonio pipe.

12. The system of claim 11, wherein a corner of an insertion part, at the one end of the slit and the one end of the gonio pipe, includes a filleted structure.

13. The system of claim 12, wherein a radius of curvature of the filleted structure of the corner of the insertion part is 3 mm or more.

14. The system of claim 11, wherein a hardness of the gonio pipe is higher than a hardness of the frictional column.

15. The system of claim 14, wherein the gonio pipe includes copper.

16. The system of claim 14, wherein the frictional column includes one of polyester ether ketone (PEEK), polyamide (PA), and duraflon.

17. The system of claim 8, wherein the specimen mounting part includes:
a mounting body;
a fastening screw;
a fixing plate configured to fix the specimen and having a hollow central area such that the specimen is precisely observed; and
a fixing pin configured to press opposite ends of the fixing plate when one side thereof is connected to the fastening screw to fasten the fastening screw.

18. The system of claim 8, wherein a perimeter of the upper support member includes one of a triangular shape, a rectangular shape, and a pentagonal shape, and
wherein a perimeter of the frictional column includes one of a pentagonal shape, a hexagonal shape, and an octagonal shape.

19. A method for observing a specimen, the method comprising:
mounting the specimen in a holder;
inserting the holder into a gonio pipe of a goniometer stage; and
observing the specimen while causing electron beams to pass through the specimen,
wherein the holder includes:
a handle part;
a specimen mounting part to which the specimen is mounted;
a coupling part connecting the handle part and the specimen mounting part; and
a guide pin coupling the holder and the goniometer stage,
wherein the guide pin includes:
a support part; and
a frictional column coupled to the support part,
wherein the support part includes:
a lower support member including a spiral screw shape on an outer surface thereof to be coupled to the holder; and
an upper support member having a column shape on the lower support member, and
wherein the frictional column surrounds an outer surface of the upper support member.

20. The method of claim 19, wherein the gonio pipe includes a slit extending from an end of the gonio pipe, into which the guide pin is inserted, and
wherein a corner of an insertion part of the gonio pipe, defined by the slit at the end of the gonio pipe, is rounded.
